(19) United States
(12) Patent Application Publication
(10) Pub. No.: US 2024/0186176 A1
(43) Pub. Date: Jun. 6, 2024

(54) STAGE ACTUATOR PARTICLE SHIELD

(71) Applicant: Onto Innovation Inc., Wilmington, MA (US)

(72) Inventors: Paul Yamasaki, San Jose, CA (US); Robin Preet Dhillon, Hayward, CA (US)

(73) Assignee: Onto Innovation Inc., Wilmington, MA (US)

(21) Appl. No.: 18/522,038

(22) Filed: Nov. 28, 2023

Related U.S. Application Data
(60) Provisional application No. 63/429,912, filed on Dec. 2, 2022.

(51) Int. Cl. H01L 21/687; B25B 11/00

(52) U.S. Cl. CPC H01L 21/68792; B25B 11/005; H01L 21/68742

(57) ABSTRACT

A particle shield for an actuator housing in a semiconductor equipment system includes a ring that mounts to the actuator housing, and a plate that mounts to a Z-axis stage that moves relative to the actuator housing. The ring includes a collar that extends from a flange in the Z coordinate direction. The collar and the plate, or a skirt that extends from the outside perimeter of the plate in the Z coordinate direction, remain within a same plane and do not contact each other during movement in the Z coordinate direction by the first Z-axis stage. The plate and the collar may be coaxial so that plate and the collar do not contact each other during rotation of the Z-axis stage relative to the actuator housing. A second Z-axis stage to which a chuck may be mounted passes through an aperture in the plate.

### CROSS REFERENCE TO RELATED APPLICATIONS

This application claims priority under 35 USC 119 to U.S. Provisional Application No. 63/429,912, filed Dec. 2, 2022, entitled “STAGE ACTUATOR PARTICLE SHIELD,” which is incorporated by reference herein in its entirety.

### FIELD OF THE DISCLOSURE

Subject matter described herein is related generally to a particle shield, and more particularly to a particle shield for an actuator that moves a semiconductor equipment stage.

### BACKGROUND

Semiconductor and other similar industries often use metrology or inspection equipment for evaluation of substrates during processing and semiconductor fabrication equipment for making integrated circuits on a wafer. During metrology or inspection, relative movement between the optical head and the substrate is often necessary, e.g., in order to measure or inspect multiple areas on the substrate and to place the substrate in the proper focal position with respect to the optical head. The same is true for fabrication equipment. Various types of stages have been developed to quickly place a substrate at a desired measurement or inspection location with respect to the optical head. For example, stages may move a substrate (or optical head) using Cartesian (i.e., X and Y) coordinates, using Polar (i.e., R and θ) coordinates, or some combination of the two. Additionally, a stage may move a substrate (or optical head) along a vertical (i.e., Z) coordinate for focusing or for loading and unloading a substrate. Actuators are used to produce movement of the stages. Actuators, however, necessarily require physical movement between components and may generate particles. The particles may be small and sparse, but it is important to avoid particle contamination of substrates used in semiconductor and similar industries.

### SUMMARY

In some aspects, the techniques described herein relate to a particle shield with two degrees of freedom for an actuator housing, which may contain a first Z-axis stage, a second Z-axis stage, and a theta actuator that rotates the first Z-axis stage and the second Z-axis stage relative to the actuator housing. The particle shield may include a ring that is mounted on the actuator housing. The ring includes a flange that is coupled to the actuator housing and a collar that extends from the flange along a Z coordinate direction. The particle shield may further include a plate that is mounted to the first Z-axis stage. The plate includes an aperture through which the second Z-axis stage passes. The plate further includes a skirt at an outside perimeter of the plate that extends along the Z coordinate direction. The collar and the skirt are coaxial and do not contact each other during rotation of the first Z-axis stage and remain within a same plane that is orthogonal to the Z coordinate direction during movement along the Z axis by the first Z-axis stage.

In some aspects, the techniques described herein relate to a particle shield for an actuator housing containing a first Z-axis stage and a theta actuator that rotates the first Z-axis stage relative to the actuator housing. The particle shield may include a ring that is mounted on the actuator housing. The ring includes a flange that is coupled to the actuator housing and a collar that extends from the flange along a Z coordinate direction. The particle shield may further include a plate mounted to the first Z-axis stage. The collar and the plate are coaxial and do not contact each other during rotation of the first Z-axis stage relative to the actuator housing and remain within a same plane that is orthogonal to the Z coordinate direction during movement in the Z coordinate direction by the first Z-axis stage.

In some aspects, the techniques described herein relate to a particle shield for an actuator housing. The particle shield may include a ring that is mounted on the actuator housing. The ring includes a flange that is coupled to the actuator housing and a collar that extends from the flange along a Z coordinate direction. The particle shield may further include a plate mounted to a first Z-axis stage. The collar and the plate remain within a same plane-that is orthogonal to the Z coordinate direction and do not contact each other during movement in the Z coordinate direction by the first Z-axis stage.

### BRIEF DESCRIPTION OF THE DRAWINGS

FIG. 1 illustrates a schematic side view of a semiconductor equipment system that includes an actuator assembly.

FIG. 2 illustrates a perspective view of the actuator assembly shown in FIG. 1.

FIG. 3 illustrates a perspective view of a particle shield mounted to the actuator assembly to reduce particle contamination.

FIG. 4 illustrates a side view of a portion of the particle shield mounted to the actuator assembly to reduce particle contamination.

FIGS. 5A and 5B illustrate perspective views of different implementations of the ring portion of the particle shield.

FIGS. 6A and 6B illustrate perspective views of different implementations of the plate portion of the particle shield.

FIGS. 7A-7E illustrates side views of different implementations of a ring and a plate for the particle shield.

FIGS. 8A and 8B illustrate top views of different implementations of a ring and a plate for the particle shield.

### DETAILED DESCRIPTION

A source of particle contamination during metrology, fabrication, or inspection of semiconductor (or other similar industry) substrates is due to moving components in the stage(s) that provide relative motion between the substrate and the optical head or tool. For example, during motion, materials within the internal volume of the stage, e.g., the actuator, rub together producing particles. Additionally, particles from lubricants can become airborne. The particles may escape the internal volume of the stage and settle on the substrate, thereby contaminating the substrate.

The motion required by semiconductor equipment may be complex. For example, while stages may move a substrate (or optical head) using Cartesian (i.e., X and Y) coordinates, such motion requires a large area to access all locations on a substrate. The use of Polar (i.e., R and θ) coordinates pre-aligns the substrates Cartesian coordinates with that of the stage, but requires rotational motion in addition to linear motion. Moreover, motion along the Z coordinate is used for focusing, as well as for loading and unloading a substrate. Additionally, multiple stages may be used to perform the same motion, e.g., a coarse motion stage and a fine motion stage. The resulting assembly may have multiple degrees of freedom (DOF), where each degree of freedom may contribute to particle generation and contamination of the substrate.

As discussed herein, a particle shield for an actuator housing of a stage may be used to reduce or eliminate the amount of particles that escape the internal volume of the stage while permitting one or more DOFs for the stage. For example, the actuator housing may include a Z-axis stage for moving a substrate along the Z-axis or both a Z-axis stage and a θ coordinate stage for rotating the substrate in the θ direction. The particle shield, for example, includes a ring which has a flange that is coupled to the actuator housing and a collar that extends from the flange along a Z-axis. The particle shield further includes a separate plate that is mounted to a Z-axis stage. The plate and the collar of the ring remain within a same plane but do not contact each other during movement along the Z axis by the Z-axis stage. The outer perimeter of the plate, for example, may be positioned near the inner perimeter of the collar, e.g., no more than 2 mm, and may be less than 1.5 mm, 1 mm, or 0.5 mm, but does not contact the collar during motion. In some implementations, the plate and the inner perimeter of the collar may be circular, permitting rotation (θ direction) of the Z-axis stage without contacting each other. Additionally, the plate may include a skirt at the outside diameter that extends along the Z-axis, where the collar and the skirt remain within a same plane during movement along the Z axis by the Z-axis stage. The plate may further include an aperture through which a second Z-axis stage passes, e.g., to permit both coarse and fine vertical motion.

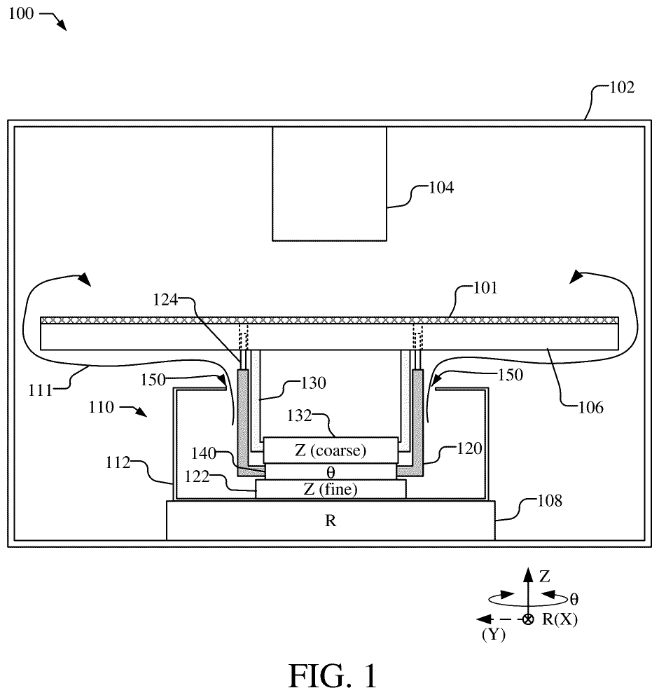

FIG. 1, by way of example, is a schematic side view of a semiconductor equipment system 100 that includes an actuator assembly 110 that is a source of particle contamination. The actuator assembly 110 is illustrated as enabling motion in the Z coordinate axis (both coarse and fine motion) as well as rotational Theta (θ) motion, and accordingly, is sometimes referred to as a ZT Box.

The semiconductor equipment system 100 is illustrated as including a housing 102 and an optical head or tool 104. The tool 104 can be a lithography camera, optical or other system for metrology/inspection, a drilling tool, a plating tool, an ion implantation tool, or any other metrology tool or semiconductor fabrication tool. A chuck 106 for holding a substrate 101 is illustrated as being mounted to the actuator assembly 110. Additionally, as illustrated, the semiconductor equipment system 100 may include a linear (R) stage 108 upon which the actuator assembly 110 is located. In some implementations, stage 108 may produce motion along both the X and Y motion coordinates.

The actuator assembly 110 includes the external housing 112, in which is contained a first (e.g., fine) Z axis stage 120, a second (e.g., coarse) Z axis stage 130, and a Theta actuator 140. The Theta actuator 140 is operable to rotate both the first Z axis stage 120 and the second Z axis stage 130 illustrated by the Theta (θ) coordinate. Additionally, as illustrated, the first Z axis stage 120 is mounted to the Theta actuator 140, which is mounted to a Z (fine) actuator 122, which operates to move the first Z axis stage 120, the Theta actuator 140, and the second Z axis stage 130 along the Z coordinate direction, and the second Z axis stage 130 is mounted on a second Z (coarse) actuator 132, which operates to move the second Z axis stage 130 along the Z coordinate direction. The chuck 106 is illustrated as being mounted on the second Z axis stage 130.

Additionally, as illustrated, a plurality of lift pins 124 may be coupled to the first Z axis stage 120 and may pass through the chuck 106. When the second Z stage 130 is lowered, thereby lowering the chuck 106, the lift pins 124 will raise above the top surface of the chuck 106 to load or unload a substrate 101 from the chuck, e.g., by permitting access for a paddle to carry the substrate 101 to and from the chuck 106.

It should be understood that the actuator assembly 110 is illustrative and that an actuator assembly may have other configurations. For example, the types of stages and actuators may be varied. For example, the actuator assembly 110 is illustrated as having two DOFs (Z and θ), but may have a single DOF, e.g., Z or θ. Moreover, the actuator assembly 110 may include only a single Z axis stage, e.g., stage 120. In some implementations, the order of the stages and actuators may be varied. For example, the Theta actuator 140 is illustrated as being mounted between the Z (fine) actuator 122 and the Z (coarse) actuator 132, but in some implementations, the first Z axis stage 120 may be mounted to the Z (fine) actuator 122 and the Theta actuator 140 may be mounted under both the Z (fine) actuator 122 and the Z (coarse) actuator 132, or the Z actuator 122 may be a coarse motion actuator and the Z actuator 132 may be a fine motion actuator.

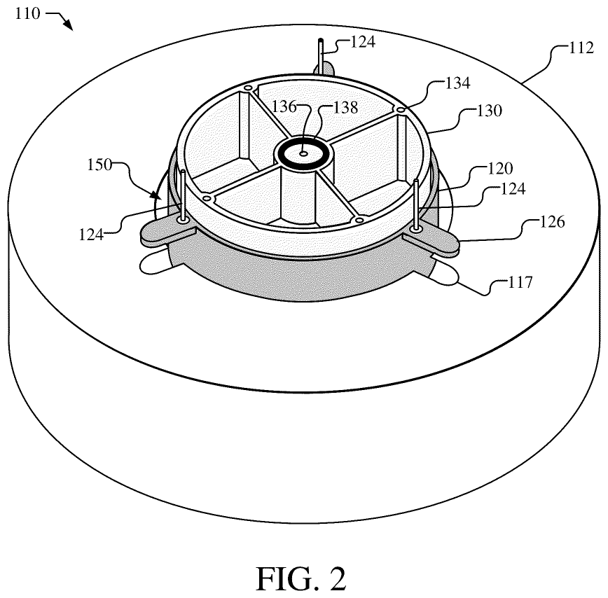

FIG. 2, by way of example, is a perspective view of the actuator assembly 110 shown in FIG. 1, illustrating the external housing 112, the first Z axis stage 120 and the second Z axis stage 130. The Z actuators 122 and 132, and the Theta actuator 140 are not shown in FIG. 2. As illustrated, the second Z axis stage 130 may include mounting holes 134 with which a chuck 106 may be mounted (e.g., bolted) to the second Z axis stage 130. Additionally, the second Z axis stage 130 includes an aperture 136 and gasket 138, which may be used to apply a vacuum to the chuck 106, if desired, for holding a substrate. The lift pins 124 may be mounted to the first Z axis stage 120 on tabs 126. Tabs 126, for example, may permit the lift pins 124 to be mounted at different positions (radius) to accommodate different chuck designs. As illustrated, the housing 112 may include cut-outs 117 that are larger than tabs 126 to permit the first Z axis stage 120 to move the tabs 126 below the top surface of the housing 112.

Sources of particle contamination from the actuator assembly 110 includes moving components, such as the actuators 122, 132, and 140 (shown in FIG. 1), as well as stages 120 and 130, which may rub against other elements creating particles. Additionally, particles from lubricants can become airborne. As illustrated by arrows 111 in FIG. 1, particles generated from within the actuator assembly 110 may escape between the space 150 (illustrated in FIGS. 1 and 2) between the housing 112 and the moving components, e.g., stage 120, and may land on and contaminate the substrate 101. A vacuum may be applied to the internal volume of the housing 112, e.g., in an attempt to evacuate any generated particles from within the housing 112. With a relatively large space 150 there is insufficient constriction between the housing 112 and the stage 120, and the vacuum may not be sufficient to prevent particles from escaping the housing along the paths illustrated by arrows 111.

A particle shield that includes a ring that mounts to the actuator housing 112 and a separate plate that mounts to Z-axis stage 120 may be used to significantly reduce particle contamination of the substrate 101 by reducing the cross sectional area of the space through which the particle contamination may exit the housing 112 and by increasing a pressure differential between the internal volume of the housing 112 and ambient atmosphere (outside the housing 112) to improve evacuation of particles from the housing 112.

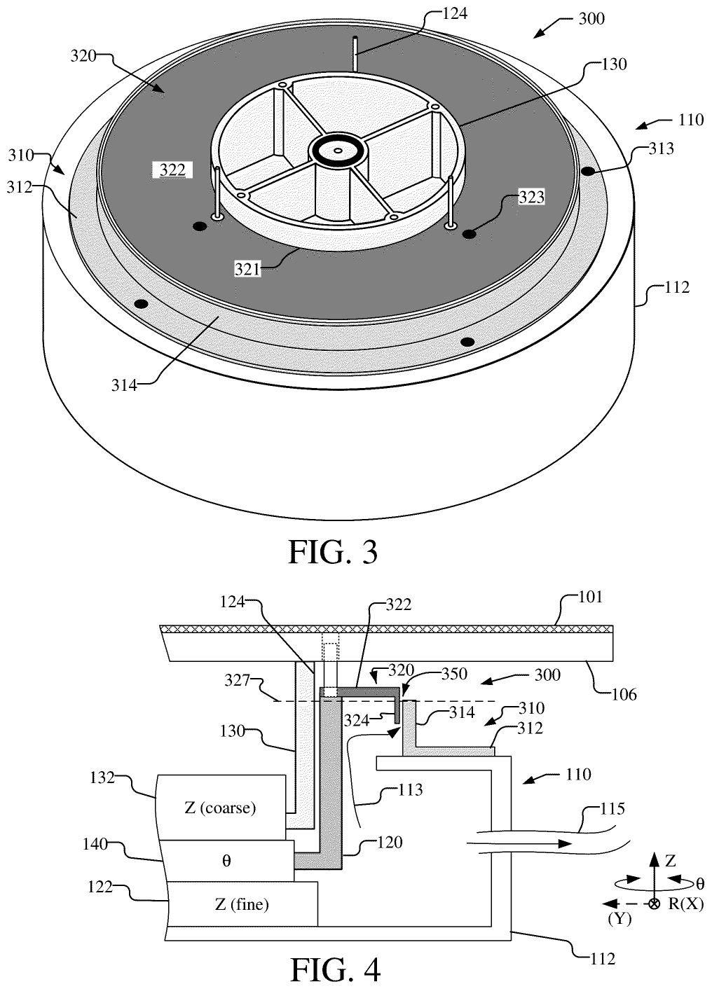

FIG. 3, by way of example, is a perspective view of a particle shield 300 mounted to the actuator assembly 110 shown in FIGS. 1 and 2, and FIG. 4 illustrates a side view of a portion of the particle shield 300 mounted to the actuator assembly 110 to reduce particle contamination.

As illustrated, the particle shield 300 includes a ring 310 with a flange 312 that is mounted to the housing 112, e.g., the top surface of the housing 112, with screws or bolts 313 (shown in FIG. 3), or other appropriate mounting means. The ring 310 further includes a collar 314 that extends from the flange 312 along the Z-coordinate direction. As illustrated, in FIG. 3, the collar 314 may extend upward in the Z direction, but with modification of the ring 310, the collar 314 may extend downward along the Z direction.

The particle shield 300 further includes a plate 320 that is mounted to the Z axis stage 120, which is shown in FIG. 4 but is hidden from view in FIG. 3. The plate 320 may include a cover 322, which may include an aperture 321 through which the second Z axis stage 130 (if present) passes. FIG. 3 illustrates the aperture 321 as circular to accommodate a circular second Z axis stage 130, but it should be understood that the second Z axis stage 130 may have other geometric shapes, e.g., square, triangle, etc., and the aperture 321 will have a corresponding shape to accommodate the shape of the second Z axis stage 130. The plate 320 may be mounted to the Z axis stage 120 with screws or bolts 323 (shown in FIG. 3) or other appropriate mounting means, e.g., at tabs 126 shown in FIG. 2. The lift pins 124 mounted to the Z axis stage 120 may extend through apertures in the plate 320. The plate 320 may include a skirt 324 at an outside perimeter of the plate 320 that extends along the Z-coordinate direction. In general, the skirt 324 may extend in an opposite direction than the collar 314. The skirt 324 and the collar 314 may be concentric to permit rotation of the plate 320 (e.g., skirt 324) within the collar 314 without contact during rotation of the Z axis stage 120 relative to the housing 112 produced by the Theta actuator 140. Additionally, the skirt 324 and the collar 314 lengths are configured so that so that no contact with the housing 112 or chuck 106 is made, e.g., as illustrated in FIG. 4, the collar 314 does not contact the chuck 106 and the skirt 324 does not contact the housing 112 through the full range of Z coordinate movement by the Z axis stage 120. Further, the plate 320 (e.g., skirt 324) and the collar 314 are configured so that the plate 320 (e.g., skirt 324) and the collar 314 both remain within a same plane (illustrated by dotted line 327 in FIG. 4) that is orthogonal to the Z axis during through the full range of movement in the Z coordinate direction by the Z axis stage 120. The space 350 between the plate 320 (e.g., skirt 324) and the collar 314 may be no more than 2 mm, and may be less than 1.5 mm, 1 mm, or 0.5 mm. The close relation of the plate 320 (e.g., skirt 324) and the collar 314 reduces the cross sectional area of the space 350 through which particles may exit the housing 112 (illustrated by arrow 113). Moreover, the close relation of the plate 320 (e.g., skirt 324) and the collar 314 increases the pressure differential between the internal volume of the housing 112 and ambient atmosphere (outside the housing 112) when a vacuum 115 is applied to the internal volume of the housing 112, which improves evacuation of particles from the housing 112.

The ring 310 and plate 320 may be manufactured from the same or different materials, such as aluminum, which may be anodized or plated, e.g., with electroless nickel plating or other plating, steel, stainless steel, or a polymer, such as polytetrafluoroethylene (PTFE), polyoxymethylene (POM), polyether ether ketone (PEEK), etc. The plate 320 that is mounted on the moving Z axis stage 120, and thus, should have mass, e.g., thickness and/or material, that is small enough to not significantly affect the performance characteristics of the actuators 122, 140, and/or the parameters of the motion profile of one or both actuators 122 and 140 may need to be modified to accommodate the additional mass and moment of inertia of the plate 320. Additionally, the thickness and/or material of the plate 320 should provide sufficient stiffness to prevent undesired vibrations.

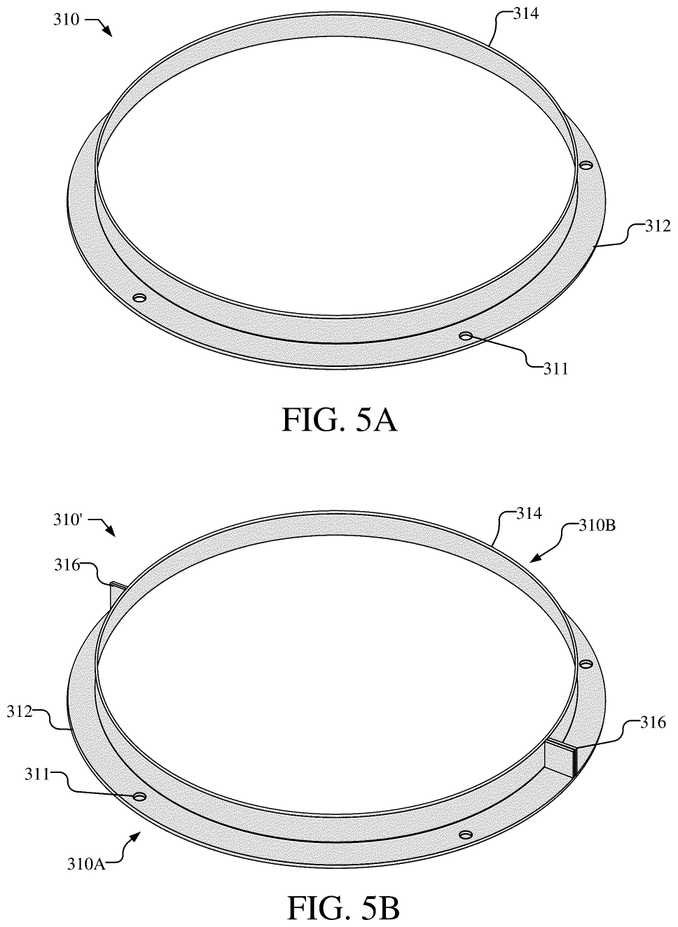

FIG. 5A, by way of example, is a perspective view of the ring 310 portion of the particle shield 300 illustrated in FIGS. 3 and 4. The ring 310 may be a single unit that includes a flange 312 and a collar 314 that is illustrated as extending upwards from the flange 312, e.g., along the Z-axis. The flange 312 is illustrated as having a circular outside diameter, but may have any desired shape. The flange 312 may include a plurality of apertures 311 for fastening the ring 310 to the housing 112 of the actuator assembly 110 with screws or bolts 313 (shown in FIG. 3). The collar 314 is illustrated as having a circular inside perimeter, which enables rotation of a circular plate 320 (shown in FIGS. 3 and 4) along the Theta (θ) coordinate. If desired, the inside perimeter of the collar 314 may have other geometric shapes if rotation of the plate 320 relative to the ring 310 (i.e., rotation of the Z axis stage plate 120 relative to the housing 112 shown in FIG. 4)) is not used.

FIG. 5B, by way of example, is a perspective view of another implementation of a ring 310′ portion of the particle shield 300. The ring 310′ illustrated in FIG. 5B is similar to ring 310 illustrated in FIG. 5A, including a flange 312 with apertures 311 and an upward extending collar 314. Unlike ring 310, however, ring 310′ is formed from separate sections. For example, as illustrated in FIG. 5B, the ring 310 may include two separable sections 310A and 310B, which are joined via tabs 316 that extend from the flange 312 and collar 314 of each section 310A and 310B. The tabs 316 from sections 310A and 310B may be press fit together or otherwise coupled together when mounted on the housing 112 of the actuator assembly 110. The use of multiple separable sections to form the ring 310′ may be advantageous to ease assembly and to simplify access to calibration screws, e.g., wedge and wobble lock-down screws, on the actuator assembly 110 (not shown) that may be otherwise hidden by the ring 310′.

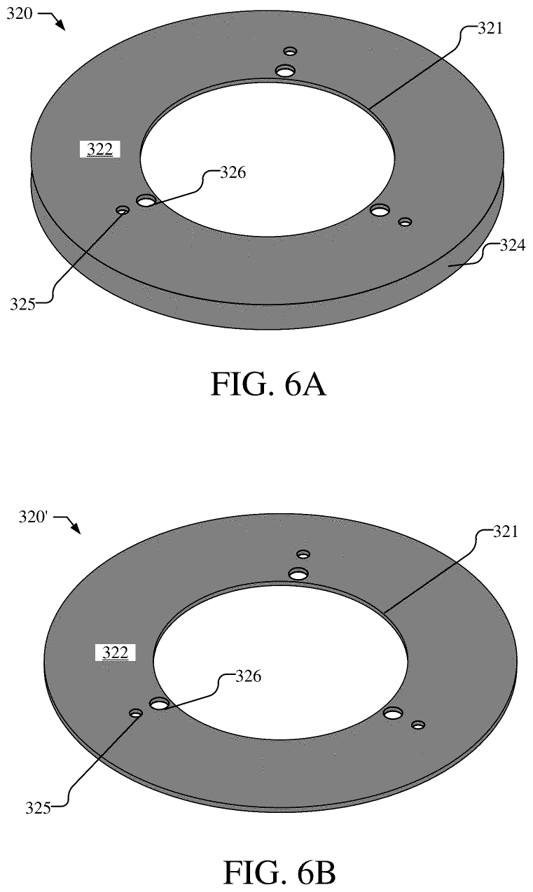

FIG. 6A, by way of example, is a perspective view of the plate 320 portion of the particle shield 300 illustrated in FIGS. 3 and 4. The plate 320 may be a single unit that includes a cover 322 and a skirt 324 that is illustrated as extending downwards from the cover 322, e.g., along the Z-axis. The cover 322 may include an aperture 321 through which the second Z axis stage 130 (if present) passes through. The plate 320 may include a plurality of apertures 325 for fastening the plate 320 to the Z axis stage 120 with screws or bolts 323 (shown in FIG. 3). Additionally, the plate 320 may include a plurality of apertures 326 through which lift pins 124 may pass. The plate 320 (e.g., skirt 324) is illustrated as having a circular outside perimeter, which enables rotation of a plate 320 within the collar 314 of the ring 310 along the Theta (θ) coordinate. If desired, the outside perimeter of the plate 320 (e.g., skirt 324) may have other geometric shapes, which matches the inside perimeter of the collar 314, if rotation of the plate 320 relative to the ring 310 (i.e., rotation of the Z axis stage plate 120 relative to the housing 112 shown in FIG. 4)) is not used.

FIG. 6B, by way of example, is a perspective view of another implementation of a plate 320′ portion of the particle shield 300. The plate 320′ illustrated in FIG. 6B is similar to plate 320 illustrated in FIG. 6A, including the cover 322 and apertures 321, 325, and 326. Unlike plate 320, however, plate 320′ does not include a downward extending skirt. The outside perimeter of the plate 320, for example, may serve as the skirt. In some implementations, it may be desirable for the plate 320′ to be relatively thick, e.g., compared to the plate 320, to compensate for the lack of the skirt.

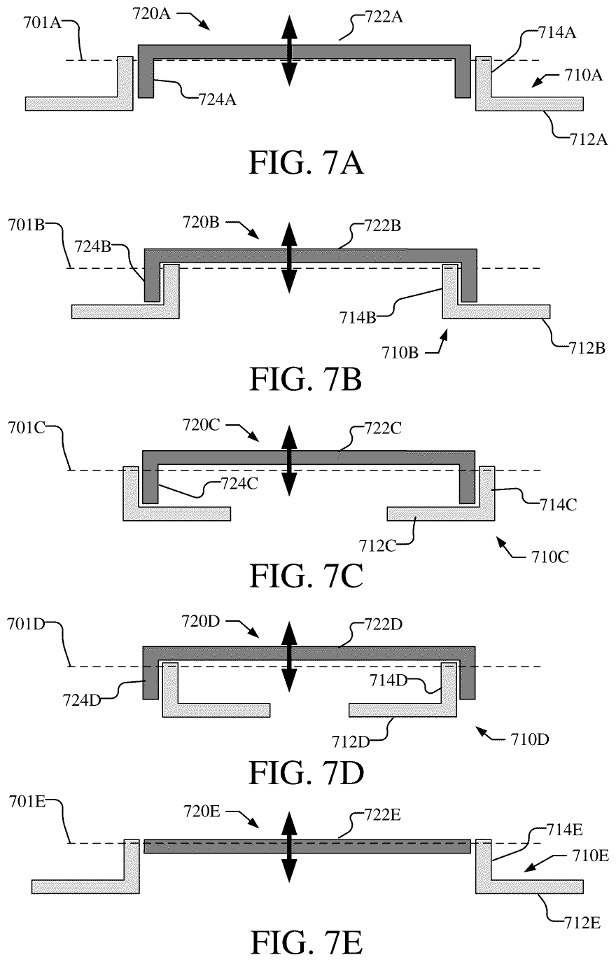

FIGS. 7A-7E, by way of example, illustrate side views of a ring and a plate that may be with the particle shield 300 shown in FIGS. 3 and 4 in accordance with various implementations.

FIG. 7A, for example, illustrates a ring 710A with an upwardly extending collar 714A at the inside perimeter of the flange 712A, and a plate 720A with a downwardly extending skirt 724A at the outside perimeter of the cover 722A. As illustrated, the skirt 724A is positioned inside the collar 714A. FIG. 7A, further illustrates a plane 701A, which is orthogonal to the Z direction, through which both the collar 714A and the skirt 724A remain during vertical motion of the plate 720A (illustrated by the double arrow) caused by movement of the Z-axis stage 120 (shown in FIG. 4).

FIG. 7B illustrates a ring 710B with an upwardly extending collar 714B at the inside perimeter of the flange 712B, and a plate 720B with a downwardly extending skirt 724B at the outside perimeter of the cover 722B. As illustrated, the skirt 724B is positioned outside the collar 714B. FIG. 7B, further illustrates a plane 701B, which is orthogonal to the Z direction, through which both the collar 714B and the skirt 724B remain during vertical motion of the plate 720B (illustrated by the double arrow) caused by movement of the Z-axis stage 120 (shown in FIG. 4).

FIG. 7C illustrates a ring 710C with an upwardly extending collar 714C at the outside perimeter of the flange 712C, and a plate 720C with a downwardly extending skirt 724C at the outside perimeter of the cover 722C. As illustrated, the skirt 724C is positioned inside the collar 714C. FIG. 7C, further illustrates a plane 701C, which is orthogonal to the Z direction, through which both the collar 714C and the skirt 724C remain during vertical motion of the plate 720C (illustrated by the double arrow) caused by movement of the Z-axis stage 120 (shown in FIG. 4).

FIG. 7D illustrates a ring 710D with an upwardly extending collar 714D at the outside perimeter of the flange 712D, and a plate 720D with a downwardly extending skirt 724D at the outside perimeter of the cover 722D. As illustrated, the skirt 724D is positioned outside the collar 714D. FIG. 7D, further illustrates a plane 701D, which is orthogonal to the Z direction, through which both the collar 714D and the skirt 724D remain during vertical motion of the plate 720D (illustrated by the double arrow) caused by movement of the Z-axis stage 120 (shown in FIG. 4).

FIG. 7E illustrates a ring 710E, with an upwardly extending collar 714E at the inside perimeter of the flange 712E, and a plate 720E, which includes only a cover 722E without a skirt. As illustrated, the outside perimeter of the cover 722E is positioned inside the collar 714E. FIG. 7E, further illustrates a plane 701E, which is orthogonal to the Z direction, through which both the collar 714E and the cover 722E remain during vertical motion of the plate 720E (illustrated by the double arrow) caused by movement of the Z-axis stage 120 (shown in FIG. 4).

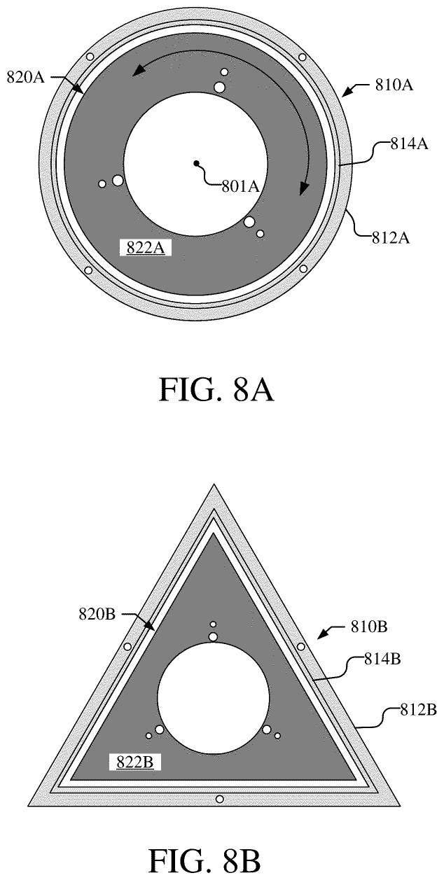

FIGS. 8A and 8B, by way of example, illustrate top views of a ring and a plate that may be with the particle shield 300 shown in FIGS. 3 and 4 in accordance with various implementations. It should be understood that the implementations illustrated in FIGS. 8A or 8B may be used in conjunction with any of the implementations illustrated in FIGS. 7A-7E.

FIG. 8A, for example, illustrates a ring 810A with collar 814A at the inside perimeter of the flange 812A, and a plate 820A, which may include a skirt (not shown) at the outside perimeter of the cover 822A. The cover 822A (or skirt if present) is positioned inside the collar 814A. As illustrated in FIG. 8A, the plate 820A and the ring 810A and the inside perimeter of the collar 814A are circular and may be separated by no more than 2 mm, and may be less than 1.5 mm, 1 mm, or 0.5 mm, to reduce the cross sectional area through which particles may exit. The outside perimeter of the cover 822A (e.g., the outside perimeter of the skirt if present) and the inside perimeter of the collar 814A are coaxial, e.g., both are centered on the same center point 801A, which enables contactless rotation of the plate 820A within the collar 814A, as illustrated by the double arrow. Thus, both rotational motion and vertical motion along the Z axis is possible thereby enabling a particle shield with two degrees of freedom.

FIG. 8B illustrates a ring 810B with collar 814B at the inside perimeter of the flange 812B, and a plate 820B, which may include a skirt (not shown) at the outside perimeter of the cover 822B. The cover 822B (or skirt if present) is positioned inside the collar 814B. As illustrated in FIG. 8B, the plate 820B and the ring 810B, and more particularly, outside perimeter of the cover 822B (e.g., the outside perimeter of the skirt if present) and the inside perimeter of the collar 814B, are not circular but are similar triangles. The outside perimeter of the cover 822B (e.g., the outside perimeter of the skirt if present) and the inside perimeter of the collar 814B may have other geometric shapes than triangular or circular, but they should be the same shape. The outside perimeter of the cover 822B (e.g., the outside perimeter of the skirt if present) and the inside perimeter of the collar 814B may be separated by no more than 2 mm, and may be less than 1.5 mm, 1 mm, or 0.5 mm, to reduce the cross sectional area through which particles may exit. With use of geometric shapes other than circular, rotational motion of the plate 820B relative to the ring 810B is not possible, but vertical motion along the Z axis is possible thereby enabling a particle shield with a single degree of freedom.

The above description is intended to be illustrative, and not restrictive. For example, the above-described examples (or one or more aspects thereof) may be used in combination with each other. Other implementations can be used, such as by one of ordinary skill in the art upon reviewing the above description. Also, various features may be grouped together and less than all features of a particular disclosed implementation may be used. Thus, the following aspects are hereby incorporated into the above description as examples or implementations, with each aspect standing on its own as a separate implementation, and it is contemplated that such implementations can be combined with each other in various combinations or permutations. Therefore, the spirit and scope of the appended claims should not be limited to the foregoing description.

What is claimed is:

1. A particle shield with two degrees of freedom for an actuator housing, the actuator housing containing a first Z-axis stage, a second Z-axis stage, and a theta actuator that rotates the first Z-axis stage and the second Z-axis stage relative to the actuator housing, the particle shield comprising:
a ring mounted on the actuator housing, the ring comprising a flange that is coupled to the actuator housing and a collar that extends from the flange along a Z coordinate direction; and
a plate mounted to the first Z-axis stage, the plate comprising an aperture through which the second Z-axis stage passes, and a skirt at an outside perimeter of the plate that extends along the Z coordinate direction, wherein the collar and the skirt are coaxial and do not contact each other during rotation of the first Z-axis stage and remain within a same plane that is orthogonal to the Z coordinate direction during movement along the Z coordinate direction by the first Z-axis stage.

2. The particle shield of claim 1, wherein the skirt is inside the collar.

3. The particle shield of claim 1, wherein collar is inside the skirt.

4. The particle shield of claim 1, wherein the collar is circular and the skirt is circular.

5. The particle shield of claim 1, wherein the collar and the skirt are separated by no more than 2 mm.

6. The particle shield of claim 1, wherein the skirt and the collar remain within the same plane through a full range of motion along the Z coordinate direction by the first Z-axis stage.

7. The particle shield of claim 1, wherein the plate further comprises a plurality of apertures through which lift pins extend.

8. The particle shield of claim 1, wherein a chuck is mounted to the second Z-axis stage.

9. A particle shield for an actuator housing containing a first Z-axis stage and a theta actuator that rotates the first Z-axis stage relative to the actuator housing, the particle shield comprising:
a ring mounted on the actuator housing, the ring comprising a flange that is coupled to the actuator housing and a collar that extends from the flange along a Z coordinate direction; and
a plate mounted to the first Z-axis stage, wherein the collar and the plate are coaxial and do not contact each other during rotation of the first Z-axis stage relative to the actuator housing and remain within a same plane that is orthogonal to the Z coordinate direction during movement in the Z coordinate direction by the first Z-axis stage.

10. The particle shield of claim 9, wherein the collar and an outer perimeter of the plate are coaxial and do not contact each other during rotation of the first Z-axis stage.

11. The particle shield of claim 9, wherein the collar and an outer perimeter of the plate are separated by no more than 2 mm.

12. The particle shield of claim 9, wherein the plate and the collar remain within the same plane through a full range of motion along the Z coordinate direction by the first Z-axis stage.

13. The particle shield of claim 9, wherein the plate further comprises an aperture through which a second Z-axis stage passes.

14. The particle shield of claim 13, wherein a chuck is mounted to the second Z-axis stage.

15. The particle shield of claim 9, wherein the plate further comprises a plurality of apertures through which lift pins extend.

16. A particle shield for an actuator housing, the particle shield comprising:
a ring mounted on the actuator housing, the ring comprising a flange that is coupled to the actuator housing and a collar that extends from the flange along a Z coordinate direction; and
a plate mounted to a first Z-axis stage, wherein the collar and the plate remain within a same plane that is orthogonal to the Z coordinate direction and do not contact each other during movement in the Z coordinate direction by the first Z-axis stage.

17. The particle shield of claim 16, wherein the actuator housing contains a theta actuator that rotates the first Z-axis stage relative to the actuator housing, wherein the plate and the collar are coaxial and do not contact each other during rotation of the first Z-axis stage.

18. The particle shield of claim 16, wherein an outside perimeter of the plate comprises a skirt that extends along the Z coordinate direction, and the collar and the skirt remain within a same plane during movement in the Z coordinate direction by the first Z-axis stage.

19. The particle shield of claim 16, wherein an outside perimeter of the plate and the collar are separated by no more than 2 mm.

20. The particle shield of claim 16, wherein the plate further comprises a plurality of apertures through which lift pins extend.
